(19) United States
(12) Patent Application Publication
(10) Pub. No.: US 2024/0347561 A1
(43) Pub. Date: Oct. 17, 2024

(54) VISIBLE TO LONGWAVE INFRARED PHOTODETECTOR ON SILICON

(71) Applicant: THE BOARD OF TRUSTEES OF THE UNIVERSITY OF ARKANSAS, Little Rock, AR (US)

(72) Inventors: Shui-Qing Fisher Yu, Little Rock, AR (US); Clifford King, Little Rock, AR (US); Baohua Li, Little Rock, AR (US)

(21) Appl. No.: 18/505,567

(22) Filed: Nov. 9, 2023

Related U.S. Application Data
(60) Provisional application No. 63/424,236, filed on Nov. 10, 2022.

(51) Int. Cl. H01L 27/146

(52) U.S. Cl. CPC H01L 27/1461; H01L 27/14649; H01L 27/14683

(57) ABSTRACT

In one aspect, pixel architectures for employment in photodetector apparatus and systems are described herein. A pixel, in some embodiments, comprises a silicon substrate, and one more dielectric layers over the substrate. The dielectric layers, for example, can comprise silica (SiO₂) and/or other suitable dielectric material(s). A photoactive region resides within the one or more dielectric layers, the photoactive region comprising a heterojunction formed of a first Group IVA semiconductor alloy epitaxially extending from an aperture passing through the one or more dielectric layers to the silicon substrate, and a second Group IVA semiconductor alloy extending epitaxially from the first Group IVA semiconductor alloy.

### RELATED APPLICATION DATA

The present invention claims priority pursuant to 35 U.S.C. § 119 (e) to U.S. Provisional Patent Application Ser. No. 63/424,236 filed Nov. 10, 2022 which is incorporated herein by reference in its entirety.

### STATEMENT REGARDING FEDERALLY SPONSORED RESEARCH

This invention was made with government support under contract number N00014-21-1-2899 from the Office of Naval Research. The government has certain rights in the invention.

### FIELD

The present application is directed to photodetection and imaging systems, more specifically to focal plane array imaging systems for use in the visible and/or infrared region of the electromagnetic spectrum.

### BACKGROUND

Infrared (IR) detection and imaging has been utilized in defense and civilian systems for night-vision applications. In fact, video surveillance, security camera systems, automotive night-vision systems, LiDAR systems, and integrated IR cameras in smart mobile electronics have been popular for decades. Since 1960s, the narrow gap III-V alloys (InGaAs and InSb), IV-VI (PbSnTe, PbS) and II-VI (HgCdTe) material systems have activated a degree of freedom in IR detection design due to bandgap engineering capability. However, the mature IR detection technology has high cost, hard fabrication, and low temperature operation, which has hindered research for a CMOS-compatible system that can be adapted for mass production. Over the past years, many strategies have been constructed toward the hybrid integration of III-Vs or II-Vs on a Si substrate. It is highly desirable to develop an alternative materials and methods featuring lower cost and higher temperature operation for pixels of IR cameras.

Still needed in the art are IR cameras and associated manufacturing techniques that can be integrated with mass production processes, such as CMOS-compatible growth. Further, a continued need and growth of applications for such cameras necessitates the development of synthetic pathways that can be adapted to large scale manufacture and/or have reduced manufacturing costs.

### SUMMARY

In one aspect, pixel architectures for employment in photodetector apparatus and systems are described herein. A pixel, in some embodiments, comprises a silicon substrate, and one more dielectric layers over the substrate. The dielectric layers, for example, can comprise silica (SiO₂) and/or other suitable dielectric material(s). A photoactive region resides within the one or more dielectric layers, the photoactive region comprising a heterojunction formed of a first Group IVA semiconductor alloy epitaxially extending from an aperture passing through the one or more dielectric layers to the silicon substrate, and a second Group IVA semiconductor alloy extending epitaxially from the first Group IVA semiconductor alloy. Group IVA is also Group 14 of the IUPAC Periodic Table. The first Group IVA semiconductor alloy can have a bandgap larger than the second Group IVA semiconductor alloy. The trench, in some embodiments, terminates in a n-well region of the silicon substrate, wherein the n-well extends laterally beyond the trench. Moreover, the first Group IVA semiconductor alloy can form a cathode of the photoactive region, with the second Group IVA semiconductor alloy forming an anode of the photoactive region. In some embodiments, the second Group IVA semiconductor alloy resides in a well-defined by the first Group IVA semiconductor alloy.

In some embodiments, the first and second Group IVA semiconductor alloys are independently selected from the group consisting of binary alloys and ternary alloys. The binary alloys can comprise Ge₁₋ₓSnₓ, and the ternary alloys comprise Si_{1-x-y}GeₓSn_{y}. In some embodiments, binary alloys may have the composition Ge₁₋ₓSnₓ, where 0.01≤x≤0.30, such as 0.01≤x≤0.18, 0.01≤x≤0.15, or 0.01≤x≤0.09. In addition to the absorption of visible radiation, the photoactive region, in some embodiments, can absorb electromagnetic radiation selected from the group consisting of short-wave infrared radiation (SWIR), mid-wave infrared radiation (MWIR), and long-wave infrared radiation (LWIR). The photoactive region, for example, can absorb infrared radiation having a wavelength up to 15 μm, up to 10 μm, or up to 5 μm. In some embodiments, the first and/or second Group IVA semiconductor alloys are defect free or substantially defect free. In being substantially defect free, the first and/or second Group IVA semiconductor alloys have a misfit dislocation density less than 1×10⁶ cm⁻².

In another aspect, imaging systems are described herein. An imaging system comprises an imaging wafer comprising a silicon substrate, and a pixelated focal plane array over the substrate, wherein pixels of the focal plane array comprise a photoactive region residing within one or more dielectric layers. The photoactive region comprises a heterojunction formed of a first Group IVA semiconductor alloy epitaxially extending from an aperture passing through the one or more dielectric layers to the silicon substrate, and a second Group IVA semiconductor alloy extending epitaxially from the first Group IVA semiconductor alloy. The focal plane array can have any desired number of pixels. Number of pixels can be selected according to various considerations including, but not limited to, end use or application of the imaging system, desired image resolution, spectral range imaged, and cost of device fabrication. Pixels of the focal plane array can have any composition, architecture, and/or spectral properties described herein for a pixel. In some embodiments, pixels of the focal plane array are of the same composition and/or architecture. In other embodiments, the focal plane array can be divided into groups of pixels, wherein pixels of the same group share the same architecture and properties. In this way, multiple regions of the electromagnetic spectrum can be sampled by a single focal plane array. For example, in some embodiments, the focal plane array can have three groups of pixels, a first group dedicated to SWIR imaging, second group dedicated to MWIR imaging, and a third group dedicated to LWIR imaging. The pixels of the first, second and third groups can share the same pixel architecture described herein and shown in FIGS. 1-3. However, the composition of the photoactive region is varied according to the desired absorption profile of the pixel.

A read-out integrated circuit (ROIC) wafer is integrated with the imaging wafer. In some embodiments, the ROIC is monolithically integrated with the imaging wafer. Alternatively, the ROIC is integrated with the imaging wafer via one or more bonding techniques, including metal bonding, silica to silica bonding or silicon to silicon bonding.

These and other embodiments are further described in the following detailed description.

### BRIEF DESCRIPTION OF THE DRAWINGS

FIG. 1 illustrates a cross-sectional view of a pixel architecture according to some embodiments.

FIG. 2 further illustrates the architecture of the photoactive region of FIG. 1.

FIG. 3 illustrates a cross-sectional view of a pixel architecture according to some embodiments.

FIG. 4 illustrates a method of selecting a lattice mismatched heterostructure for producing a photoactive region with desired absorption profile according to some embodiments.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

The following non-limiting examples provide further disclosure of the details disclosed in the foregoing Summary.

In this example, a photodetector and single photon avalanche photodetector (SPAD) are made using a semiconductor region integrated on a silicon wafer sensitive to infrared radiation with cutoff wavelengths up to 15 μm (SWIR, MWIR and LWIR spectral regions). The exemplary device uses GeSn as the absorptive semiconductor material and SiGeSn as the lower doped cathode region. This heterojunction forms a layer structure compatible with a conventional CMOS process using the method disclosed in U.S. Pat. Nos. 7,012,314 and 7,297,569 whereby nearly dislocation free semiconductor isolated regions are formed by aspect ratio trapping (ART) through selective epitaxial growth and chemical mechanical polishing. The use of GeSn/SiGeSn as an example should not be considered as limiting since many other crystalline semiconductors such as Si_{1-x-y}GeₓSn_{y} and Ge₁₋ₓSnₓ will benefit from the proposed processes where 0≤x,y≤1. If a CMOS or bipolar-CMOS (BiCMOS) process is chosen as the core, we start by fabricating both the CMOS and bipolar devices. One skilled in the art of making CMOS and bipolar devices can readily complete the details for such an effort. Since a particular CMOS process is not central to our invention, we will not describe the core CMOS process.

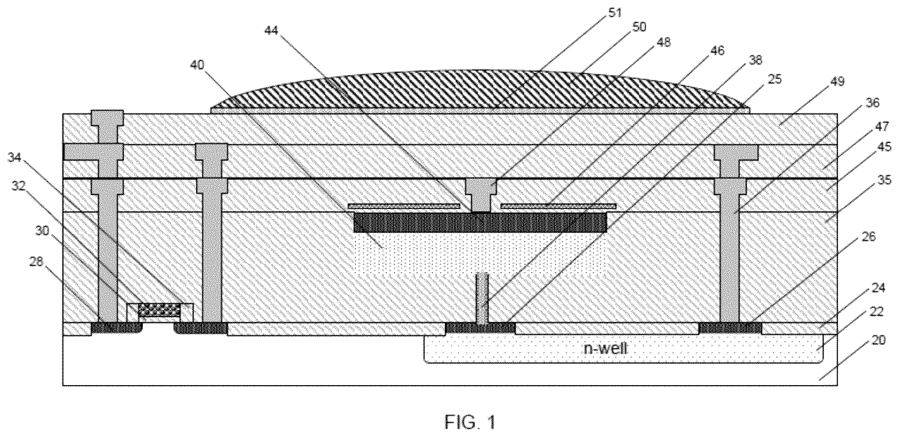

One embodiment of the SPAD device with co-integrated CMOS circuitry is shown in cross section view in FIG. 1. It includes a Si p-type doped substrate 20 in which many conventional CMOS regions such as n-well 22, shallow trench isolation 24, n+/p+source/drain 28, gate oxide 30, polycrystalline Si gate 32, and gate oxide sidewall spacer 34 are formed. The n-well 22 is isolated from the p-type substrate 20 and connects to the cathode of the photodetector via the low resistivity n+ region 25 which is also formed in the Si. Metal silicide is used on the n+/p+source/drain regions 28, but it is important not use it on the low resistivity n+ region 25 which in addition to being a low resistance layer also serves as a seeding layer for the epitaxial growth. Methods to selectively protect certain Si regions from silicide formation by use of sacrificial silicon nitride or silicon oxynitride layers are commonplace in industry and are not described in detail here. To promote single crystalline growth of Ge, such a layer is employed to shield the n+ region 25 from silicidation, but since it is removed from the n+ region 25 prior to epitaxial growth it is not shown in FIG. 1. Interlayer dielectric 35 is positioned above substrate 20 and all the elements formed in this substrate. All the components mentioned so far are found in the core CMOS process.

In the embodiment of the photodetector device according to FIG. 1, a second interlayer dielectric layer 45 is deposited on top of the prior layers and tungsten plugs 36 are formed by common methods inside interlayer dielectric layer 45 making a low resistance serial connection.

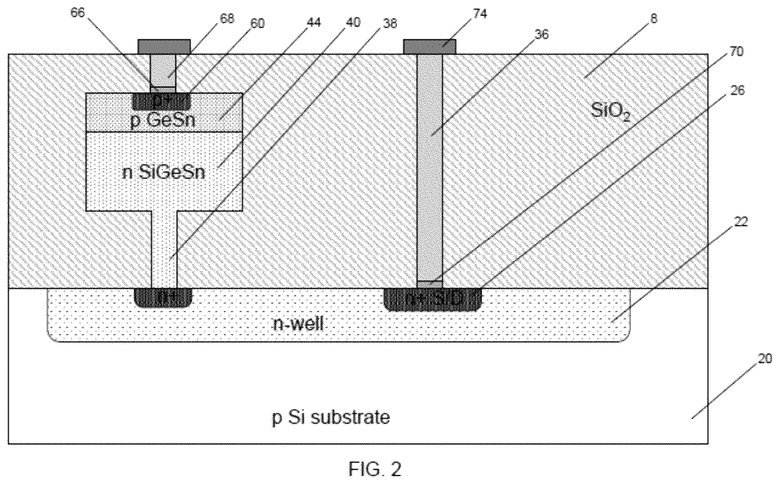

FIG. 2 shows a detailed cross-section of the envisioned heterojunction photodetector device with regions as previously described. Prior to forming the topmost tungsten plug, the photodetector device is formed in an ART produced semiconducting well. A large bandgap region 40 serving as the cathode is made by ART followed by the selective epitaxial growth of small bandgap region 44 which is to become the anode. Anode/cathode well 44/40 is connected to the low resistivity n+ region 25 by an n-type doped trench 38 which is preferably placed near the center of well 44/40. The well 44/40 is formed by using lithographic patterning and dry etching of the interlayer dielectric layers and etch stop layers to form the cavity.

A second lithographic step and dry etching defines the high aspect ratio trench 38, a type of process sequence often referred to as dual damascene in which a smaller cavity is formed inside a larger cavity. The large bandgap material is grown by selective epitaxy by first growing the in-situ n-type doped trench 38 using either phosphorus or arsenic as the dopant source. The well 40 is also grown by selective epitaxy but without any intentional doping. It is beneficial to use high purity gases for this process step as a very low background doping is desired, typically below 1×10¹⁶ cm⁻³ or even better below 1×10¹⁵ cm⁻³ in order to achieve the desired electrical field profile which helps optimize impact ionization over band-to-band tunneling. After growing the desired size to fill the well 40, excess material is removed by chemical mechanical polishing (CMP). The epitaxially grown large bandgap material fills the well 40 which results in a sidewall adhering to the shape defined by the dry etched cavity as in FIG. 2. Blanket implants without lithographic patterning into the well 40 using phosphorus or arsenic species form an n-type cathode region. After formation of the well 40, a smaller bandgap material 44 is selectively grown on top of 40 to make a heterojunction. This material may be in-situ doped p-type or implanted to form the anode of the device. All doping types may be switched to the inverse in the described regions without deviating from the invention.

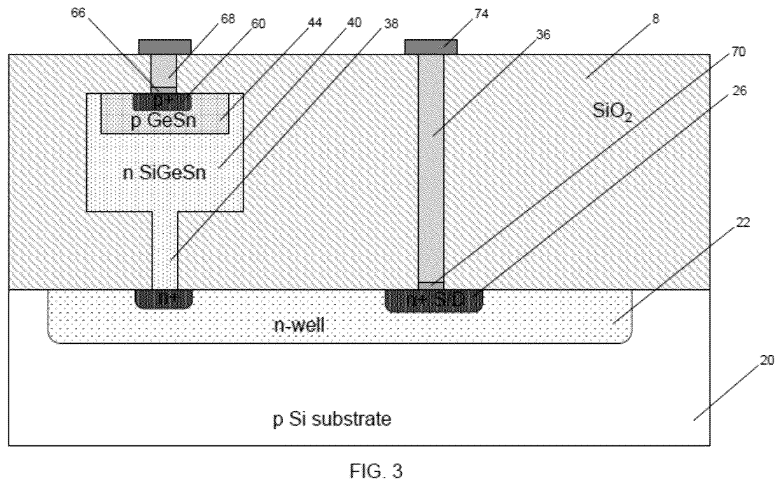

Another embodiment of a pixel architecture is illustrated in FIG. 3. This embodiment uses a different geometry to reduce dark carriers generated by surface traps in the depletion region. In this embodiment the p-n junction intersects with the top surface rather than the well edge providing an opportunity to create a low interface trap density on the surface of region 44. As is clear from FIG. 3, this embodiment shares a majority of parts with the previous embodiment and the procedure for making the photodetector according to this embodiment is the same until the formation of region 44. Rather than p-type in-situ doping during selective epitaxy of 44, n-type doping is employed at a similar level as region 40. Subsequently, the region 44 is lithographically patterned with the photoresist edges contained within the well defined by the etched dielectric well 40 and implanted p-type. A second higher dose implant within region 44 allows the formation of an ohmic contact to the anode. An implant anneal at elevated temperature as described above activates the implants without layer decomposition and the barrier

metallization 66, tungsten plug 68, and Al metallization provide a low resistance contact to the device.

In cases where the interface charge is negative along the 44/40 sidewall or where additional design margin is desired for other reasons, it may be beneficial to increase the n-type doping concentration along the 44/40 sidewall. One way to accomplish this feature is to make an additional patterning step by photo-lithography and implant phosphorus along the entire perimeter of the device so that the perimeter of the photodiode is connected to the cathode. This doped region forms a perimeter cathode which prevents depletion of 44/40 sidewall. The perimeter cathode could alternatively be formed by positive interface charges applied on 40/44 sidewall. It is critical to maintain sufficiently low doping and a large enough spacing between the perimeter cathode and p-type doped region of 44 so that the electric field in this region is well below that necessary to cause impact ionization. In FIGS. 2 and 3, the collective interlayer dielectric layers are designated as 8.

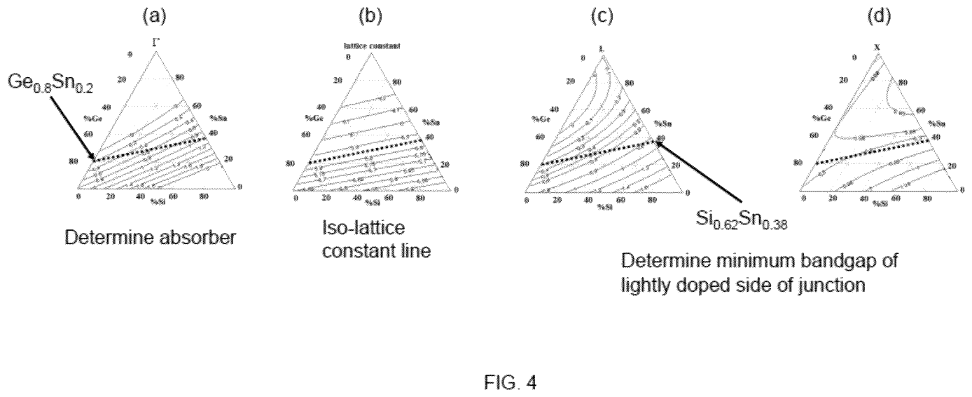

FIG. 4 discloses a method for choosing an optimum lattice matched heterostructure for use in the MWIR band with an exemplary cutoff of 5.2 μm. The ternary plots of FIG. 4 depict the variation of the bandgaps of SiGeSn in (a) the I′ valley (direct), (d) X valley (indirect), and (c) L valley (indirect) with the mole fraction of the alloy. A 5.2 μm cutoff wavelength is satisfied with a bandgap of 0.23 eV in the absorber material of the photodiode. In FIG. 4 (a), this condition is satisfied with a Ge_{0.8}Sn_{0.2} alloy since the direct transition (T) is the minimum in the band structure. Referring to FIG. 4 (b), the iso-lattice constant lines are calculated as a function of the alloy concentrations of the constituent elements. In FIG. 4 (b), the dotted line represents a fixed lattice constant of about 5.85 Å. For the lightly doped cathode side of the junction, the maximum bandgap maintaining a lattice constant of 5.85 Å is desired to minimize the dark current. A large bandgap will also increase the breakdown voltage and will reduce band-to-band tunnelling. Band-to-band tunnelling is not desired as it competes with avalanche multiplication at reverse bias and can be the dominate breakdown mechanism. Large band-to-band tunnelling can make a careful design of an avalanche photodiode impractical due to the necessary layer thicknesses and doping levels. For our current exemplary case, the maximum bandgap occurs in the L valley with a Si_{0.62}Sn_{0.38} alloy and has a value of about 0.87 eV.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A pixel of a photodetector comprising:
a silicon substrate;
one or more dielectric layers over the substrate;
a photoactive region residing within the one or more dielectric layers, the photoactive region comprising a heterojunction formed of a first Group IVA semiconductor alloy epitaxially extending from an aperture passing through the one or more dielectric layers to the silicon substrate, and a second Group IVA semiconductor alloy extending epitaxially from the first Group IVA semiconductor alloy.

2. The pixel of claim 1, wherein the first Group IVA semiconductor alloy has a bandgap larger than the second Group IVA semiconductor alloy.

3. The pixel of claim 2, wherein the aperture has an aspect ratio (length/width) greater than 1.

4. The pixel of claim 3, wherein the aspect ratio is greater than 1.7.

5. The pixel of claim 1, wherein the first and second Group IVA alloys are substantially defect free with misfit dislocation density less than 1×10⁶ cm⁻².

6. The pixel of claim 1, wherein the first Group IVA semiconductor alloy forms a cathode of the photoactive region.

7. The pixel of claim 6, wherein the trench terminates in an n-well region of the silicon substrate.

8. The pixel of claim 7, wherein the n-well extends beyond the trench.

9. The pixel of claim 8, wherein the n-well extends to a n+source/drain region.

10. The pixel of claim 6, wherein the second Group IVA semiconductor alloy forms an anode of the photoactive region.

11. The pixel of claim 1, wherein the first Group IVA semiconductor alloy is a ternary alloy.

12. The pixel of claim 11, wherein the ternary alloy is Si_{1-x-y}GeₓSn_{y}.

13. The pixel of claim 1, wherein the first Group IVA semiconductor alloy is a binary alloy.

14. The pixel of claim 13, wherein the binary alloy is Ge₁₋ₓSnₓ, wherein 0.01≤x≤0.30.

15. The pixel of claim 1, wherein the second Group IVA semiconductor alloy resides in a well defined by the first Group IVA semiconductor alloy.

16. The pixel of claim 1, wherein the photoactive region absorbs radiation in at least one region of the electromagnetic spectrum selected from the group consisting of visible radiation, short-wave infrared radiation (SWIR), mid-wave infrared radiation (MWIR), and long-wave infrared radiation (LWIR).

17. The pixel of claim 1, wherein the photoactive region has a cutoff wavelength of 15 μm or less.

18. The pixel of claim 17, wherein the cutoff wavelength is 5.2 μm.

19. An imaging system comprising:
an imaging wafer comprising a silicon substrate, and a pixelated focal plane array over the substrate, wherein pixels of the focal plane array comprise a photoactive region residing within one or more dielectric layers, the photoactive region comprising a heterojunction formed of a first Group IVA semiconductor alloy epitaxially extending from an aperture passing through the one or more dielectric layers to the silicon substrate, and a second Group IVA semiconductor alloy extending epitaxially from the first Group IVA semiconductor alloy.

20. The imaging system of claim 19, wherein the read-out integrated circuitry (ROIC) is monolithically integrated with the imaging wager.

21. The imaging system of claim 19, wherein a read-out integrated circuit (ROIC) wafer is bound to the imaging wafer.

22. The imaging system of claim 19, wherein the one or more dielectric layers comprise silica.

23. The imaging system of claim 19, wherein the first Group IVA semiconductor alloy has a bandgap larger than the second Group IVA semiconductor alloy.

24. The imaging system of claim 19, wherein the first and second Group IVA alloys are substantially defect free with misfit dislocation density less than 1×10⁶ cm⁻².

25. The imaging system of claim 19, wherein the first Group IVA semiconductor alloy forms a cathode of the photoactive region.

26. The imaging system of claim 25, wherein the trench terminates in an n-well region of the silicon substrate, the n-well region extending beyond the trench to a n+source/drain region.

27. The imaging system of claim 25, wherein the second Group IVA semiconductor alloy forms an anode of the photoactive region.

28. The imaging system of claim 19, wherein the first and second Group IVA semiconductor alloys are selected from the group consisting of binary alloys and ternary alloys.

29. The imaging system of claim 28, wherein the binary alloys comprise Ge₁₋ₓSnₓ, and the ternary alloys comprise Si_{1-x-y}GeₓSn_{y}.

30. The imaging system of claim 19, wherein the photoactive region of the pixels absorbs infrared radiation having wavelength of 15 μm or less.

31. The imaging system of claim 30, wherein the photoactive region of the pixels absorbs radiation in at least one region of the electromagnetic spectrum selected from the group consisting of visible radiation, short-wave infrared radiation (SWIR), mid-wave infrared radiation (MWIR), and long-wave infrared radiation (LWIR).

32. The imaging system claim 19, wherein the imaging system is a single photon avalanche photodetector.

33. A method of making a photodetector comprising:
providing a silicon substrate having one or more dielectric layers thereon;
forming a semiconductor well in the one or more oxide layers wherein a trench extends from the semiconductor well to the silicon substrate;
depositing a photoactive region in the semiconductor well via epitaxially growing a first Group IVA semiconductor alloy along the trench and into the photodetector well, and epitaxially growing a second Group IVA semiconductor on the first Group IVA semiconductor alloy in the photodetector well to establish heterojunction of the photoactive region.

34. The method of claim 33, wherein the trench has dimensions less than the semiconductor well.

35. The method of claim 33, wherein the trench terminates in an n-well region of the silicon substrate.

36. The method of claim 35, wherein the n-well extends beyond the trench and extends to a n+source/drain region.

37. The method of claim 33, wherein the first Group IVA semiconductor alloy forms a cathode of the photoactive region.

38. The method of claim 37, wherein the second Group IVA semiconductor alloy forms an anode of the photoactive region.

39. The method of claim 33, wherein the first and second Group IVA semiconductor alloys are selected from the group consisting of binary alloys and ternary alloys.

40. The method of claim 39, wherein the binary alloys comprise Ge₁₋ₓSnₓ, and the ternary alloys comprise Si_{1-x-y}GeₓSn_{y}.

41. The method of claim 33, wherein the photoactive region of the pixels absorbs infrared radiation having wavelength of 15 μm or less.

42. The method of claim 33, wherein the photoactive region of the pixels absorbs radiation in at least one region of the electromagnetic spectrum selected from the group consisting of visible radiation, short-wave infrared radiation (SWIR), mid-wave infrared radiation (MWIR), and long-wave infrared radiation (LWIR).
